(19) United States
(12) Patent Application Publication
(10) Pub. No.: US 2024/0295828 A1
(43) Pub. Date: Sep. 5, 2024

(54) METHOD AND MEASURING DEVICE FOR INSPECTING PHOTOMASKS, AND EUV CAMERA

(71) Applicant: Carl Zeiss SMT GmbH, Oberkochen (DE)

(72) Inventors: Senthil Lakshmanan, Jena (DE); Lutz Brekerbohm, Jena (DE); Ulrich Matejka, Jena (DE)

(21) Appl. No.: 18/587,228

(22) Filed: Feb. 26, 2024

(30) Foreign Application Priority Data
Mar. 3, 2023 (DE) 102023105270.5

(51) Int. Cl. G03F 7/00

(52) U.S. Cl. CPC G03F 7/7065; G03F 7/70033; G03F 7/7085

(57) ABSTRACT

A method for inspecting photomasks, in which a photomask is illuminated by EUV radiation emitted by an EUV radiation source). EUV radiation reflected at the photomask is guided via a projection lens to an image sensor of an EUV camera such that the photomask is imaged on the image sensor. The EUV radiation passes through a pellicle which is arranged between the projection lens and the image sensor. The invention also relates to an EUV camera and to a measuring device for inspecting photomasks.

### CROSS-REFERENCE TO RELATED APPLICATION

This application claims priority under 35 U.S.C. § 119 from German Application No. 10 2023 105 270.5, filed on Mar. 3, 2023, the entire contents of which are incorporated herein by reference.

### TECHNICAL FIELD

The invention relates to a method and a measuring device for inspecting photomasks and to an EUV camera.

### BACKGROUND

Photomasks are used in microlithographic projection exposure apparatuses, which are used to produce integrated circuits with particularly small structures. The photomask illuminated by very short-wave extreme ultraviolet radiation (EUV radiation) is imaged onto a lithography object in order to transfer the mask structure to the lithography object.

To ensure a high quality of the image created on the lithography object, it is necessary for the photomask to be true to size and not impaired by contamination. It is known practice to subject photomasks to an inspection, either prior to the operation in a microlithographic projection exposure apparatus or during an interruption of operation. To this end, a so-called aerial image of the photomask or of a portion of the photomask is created, the photomask in the process being imaged not on a lithography object but on an image sensor. Using the imaging onto the image sensor as a basis, it is possible to make an assessment as to whether the photomask is free of defects and contaminations.

The mask inspection should be performed in such a way that the measurement result is not falsified by contamination. In particular, the photomask should be prevented from experiencing contamination as a result of the mask inspection procedure.

### SUMMARY

The invention is based on the object of presenting a method and a measuring device for mask inspection and presenting an EUV camera, in the case of which the risk of contamination is reduced. The object is achieved by the features of the independent claims. Advantageous embodiments are specified in the dependent claims.

In the method according to the invention for mask inspection, a photomask is illuminated by EUV radiation emitted by an EUV radiation source. EUV radiation reflected at the photomask is guided via a projection lens to an image sensor of an EUV camera such that the photomask is imaged on the image sensor. The EUV radiation passes through a pellicle which is arranged between the projection lens and the image sensor.

The pellicle arranged between the image sensor firstly has the effect of preventing contaminations and particles emanating from the EUV camera from passing into the projection lens or other regions of the measuring device and secondly has the effect of preventing contaminations and particles emanating from the projection lens or other regions of the measuring device from passing into the EUV camera and onto the image sensor. This reduces the risk of the measurement being impaired by contamination.

The pellicle can be arranged between the image sensor and the last mirror of the projection lens. In other words, the EUV radiation between the last mirror of the projection lens and the image sensor is not reflected at a further mirror of the projection lens.

According to an aspect of the invention, the pellicle is arranged in a section of the EUV beam path in which the EUV radiation only passes through the pellicle exactly once between the EUV radiation source and the image sensor. This is a difference from conventional measuring devices, in which a pellicle is spanned over the reflectively configured EUV photomask. In that case, the EUV radiation passes through the pellicle twice, specifically once before reflection at the photomask and once after reflection at the photomask. The loss of EUV radiation power is twice as high as in the case of merely a single passage through the pellicle.

A pellicle refers to a membrane that is designed to allow EUV radiation to pass through but suppresses a passage of particles. Since matter is generally highly absorptive with regards to EUV radiation, material and structure of the pellicle must be carefully adapted in view of a use in a measuring device for mask inspection. For instance, unlike in the case of visible light, it is not possible to use glass panes as protection against contamination. The EUV radiation would be absorbed in the glass pane and would not arrive at the image sensor with sufficient intensity.

In an embodiment, the pellicle is a CNT (carbon nanotubes) pellicle, i.e. a membrane made of carbon nanotubes. The density and the bundle structure of the carbon nanotubes can be chosen such that the membrane is transmissive to EUV radiation on the one hand, while, on the other hand, particles are stopped at the membrane and cannot pass through the membrane. The membrane may be provided with a coating in order to provide the membrane with sufficient resistance to radical ions and molecules.

In an alternative embodiment, the pellicle comprises a membrane made of silicon, silicon nitride or any other silicon-containing material. If sufficiently thin, such membranes made of silicon material also provide sufficient transmissivity for EUV radiation. Then again, the capability of obstructing the passage of gaseous contamination is more pronounced in the case of pellicles made of silicon materials than in the case of CNT pellicles.

The pellicle can be a constituent part of the EUV camera. The EUV camera may comprise a camera housing which carries the image sensor and to which the pellicle is attached. The camera housing may comprise pressure equalization channels such that the same pressure is present both in the interior of the camera and in other regions of the measuring device. The projection lens, the illumination system and/or the EUV radiation source may be arranged in a vacuum chamber in which a vacuum pressure is present during the operation of the measuring device.

The camera housing may have an opening through which EUV radiation can enter into the interior of the EUV camera and be incident on the image sensor. With the exception of the opening and the pressure equalization channels, the camera housing may be sealed all around, such that the interior of the camera is protected from particles entering from the surroundings.

The pellicle may be spanned over the opening such that all EUV radiation entering through the opening into the interior passes the pellicle, i.e. travels through the pellicle. The pellicle may be sealingly flush with a housing edge surrounding the opening such that a passage of particles between the interior of the EUV camera and the surroundings at the transition between the pellicle and the housing is prevented.

The pellicle may be mounted on a frame. The pellicle may be fastened to the frame in such a way that an opening spanned by the frame is covered by the pellicle. The connection to the housing of the EUV camera may be established via the frame. The connection between the frame and the housing of the EUV camera can be a detachable connection in order to allow the pellicle to be replaced. The pellicle may need to be replaced if it has become contaminated after being used for a certain amount of time. The pellicle may be a consumable designed for regular replacement within the scope of servicing measures. The replacement of the pellicle can be undertaken manually. A motor-driven mechanism for the replacement of the pellicle is also possible.

The pellicle may extend in a plane parallel to the plane of the image sensor. The distance between the image sensor and the pellicle may be dimensioned such that particles adhering to the pellicle impair a picture recorded by the image sensor only insignificantly. In this context, there are conflicting aspects. To avoid impairments of the recorded image, it is advantageous if the pellicle is at a large distance from the image sensor. The pellicle being arranged close to the image sensor is advantageous for the compact configuration of the EUV camera or measuring device.

The EUV camera can be used in a downward configuration, in which the image sensor is oriented downward and the EUV radiation is incident on the image sensor from below. The pellicle is arranged underneath the image sensor in the case of the downward configuration. It is also possible to use the EUV camera in an upward configuration, in which the image sensor is oriented upward and the EUV radiation is incident on the image sensor from above. The pellicle is arranged above the image sensor in the case of the upward configuration.

In the case of the upward configuration, gravity assists the movement of particles in the direction of the image sensor. However, particle movements in the direction of the image sensor may also occur in the case of the downward configuration, with the result that there is also a risk of the image sensor becoming contaminated in this case. In both cases, the pellicle protects the image sensor from particles from the surroundings of the EUV camera being able to land on the image sensor.

Conversely, contamination, originating from the interior of the EUV camera, of other components of the measuring device should also be prevented. In particular, no contamination separated from the EUV camera should accumulate on the surface of the photomask. There is such a risk in particular if the EUV camera is operated in a vacuum atmosphere and there is outgassing of materials used in the camera. In general, the structure of pellicles is not designed to prevent the passage of gaseous contamination. The invention has recognized that pellicles made of silicon materials have a better effect with regards to the passage of gaseous contamination than CNT pellicles. It is for this reason that in one embodiment the pellicle is a pellicle made of a silicon material.

The projection lens of the measuring device may have a high magnification factor of for example at least 50, preferably at least 100 and more preferably at least 200. Therefore, an image sensor with a large area in comparison with the imaged partial portion of the photomask is required. The EUV camera may comprise an image sensor with a uniform sensor area which is occupied by pixels all over. The pellicle may be dimensioned such that it covers the area of the uniform sensor area, with the result that the entire sensor area is accessible to EUV radiation through the pellicle.

In other embodiments, the image sensor is configured as a sensor array, in which the sensor area of the image sensor is spanned by a plurality of sensor components. Each individual sensor component may have a sensor area occupied by pixels all over. The sensor area of the image sensor may have pixel-free regions, which may be arranged between the sensor areas of two sensor components.

The EUV camera may comprise a pellicle which is smaller than the sensor area of the image sensor, with the result that not all of the EUV radiation incident on the image sensor passes through the single pellicle. The EUV camera may comprise a plurality of pellicles which together cover the sensor area of the image sensor, with the result that all of the EUV radiation incident on the image sensor passes through one of the pellicles, preferably through exactly one of the pellicles. The plurality of pellicles may be arranged in a plane.

The plurality of pellicles may be held on frames. The frames of the pellicles may be arranged in front of pixel-free regions of the sensor area of the image sensor. In that case, the frames do not interfere with the image recording but only shield the EUV radiation where it would not be incident on pixels of the image sensor in any case. A pellicle may cover the sensor areas of one or more sensor components. In one embodiment, each sensor component is assigned its own pellicle.

In the case of a sensor array not occupied by pixels all over, there are regions of the imaged portion of the photomask for which no image information can be obtained by a single EUV image recording. Therefore, provision can be made for the position of the photomask to be modified relative to the incoming EUV beam path and for a second EUV image recording to be recorded. In the case of the second EUV image recording, the photomask may be positioned such that image information is obtained from the regions of the imaged portion of the photomask for which the first image recording supplies no image information. The method can be performed with more than two positions of the photomask and more than two EUV image recordings. A picture of the imaged portion of the photomask can be calculated from an available plurality of EUV image recordings.

In one embodiment, the device comprises an XY-positioning mechanism, by means of which the position of the photomask within an XY-plane can be modified relative to the incoming EUV beam path. The XY-plane may correspond to the plane of the photomask. The XY-positioning mechanism may be embodied such that the photomask is displaced linearly in the XY-plane. This can be used for a scanning procedure, in which a plurality of EUV image recordings belonging to the same partial portion of the photomask are recorded during a linear movement of the photomask.

In addition or as an alternative, the XY-positioning mechanism can also be used to displace the photomask relative to the incident EUV beam path such that it is possible to create aerial images of different partial portions of the photomask. In particular, the XY-positioning mechanism may be designed such that each partial portion of the photomask can be examined.

In addition or as an alternative, the XY-positioning mechanism can be used to obtain information about the state of the pellicle. To this end, a reference mask with a known surface structure, for example a uniform surface structure, can be introduced into the measuring device. A statement regarding the state of the pellicle can be made depending on how the image recording changes when the reference mask is displaced in the XY-plane.

The projection lens of the measuring device may comprise a plurality of EUV mirrors, at which the EUV radiation between the photomask and the image sensor is reflected. The optical area of an EUV mirror can be formed by a highly reflective coating. This may be a multilayer coating, especially a multilayer coating having alternating layers of molybdenum and silicon. Using such a coating, it is possible for approximately 70% of the incident EUV radiation to be reflected. The term “EUV radiation” is used to refer to electromagnetic radiation in the extreme ultraviolet spectral range with wavelengths of between 5 nm and 100 nm, in particular with wavelengths of between 5 nm and 30 nm.

Using the projection lens, EUV radiation coming from the photomask can be guided to the image sensor such that an image of the photomask, in particular of a portion of the photomask, arises on the image sensor. The portion of the photomask imaged on the image sensor may correspond to a small partial portion of the photomask.

For example, the photomask may have an edge length of between 100 mm and 200 mm and/or an area of between 100 cm² and 400 cm². The examined partial portion may have an edge length of between for example 0.1 mm and 5 mm, preferably of between 0.5 mm and 3 mm. If the partial portion is not square, the specification relates to the longer of the edge lengths. If the partial portion is also not rectangular, the specification relates to the largest dimension of the partial portion. The sensor area of the image sensor is preferably larger than the examined partial portion of the photomask, in a manner corresponding to the magnification factor of the projection lens. The dimension of the sensor area of the image sensor, defined like in the case of the examined partial portion, may for example be between 50 mm and 500 mm, preferably between 100 mm and 200 mm.

It is possible that the measuring device according to the invention comprises further pellicles which are arranged in one or more other sections of the EUV beam path, with the result that the EUV radiation passes successively through a plurality of pellicles. This may comprise further pellicles through which the EUV radiation passes exactly once. In addition or as an alternative, this may comprise pellicles which are arranged such that the EUV radiation passes through the pellicle twice.

The invention also relates to an EUV camera having a camera housing and having an image sensor, wherein the image sensor is held in the camera housing and wherein the image sensor is sensitive to EUV radiation. The camera housing spans an entrance opening provided for the entry of EUV radiation. The EUV camera comprises a pellicle such that EUV radiation entering the EUV camera through the entrance opening passes through the pellicle.

The pellicle of the EUV camera may consist of a silicon material. The pellicle may be sealingly flush with a housing edge surrounding the opening. The pellicle can be mounted on a frame, wherein the pellicle is connected to the camera housing via the frame and wherein the frame is detachably connected to the camera housing. The image sensor can be configured as a sensor array, in which the sensor area of the image sensor is spanned by a plurality of sensor components. The EUV camera may comprise a pellicle which is smaller than the sensor area of the image sensor. The plurality of pellicles can be held on a frame, wherein parts of the frame are arranged in front of pixel-free regions of the sensor area of the image sensor.

The invention further relates to a measuring device for inspecting photomasks. The measuring device comprises an illumination system, a projection lens and an EUV camera. EUV radiation emitted by an EUV radiation source is guided via the illumination system to a photomask. EUV radiation reflected at the photomask is guided via the projection lens to an image sensor of the EUV camera such that the photomask is imaged on the image sensor. The measuring device comprises a pellicle which is arranged between the projection lens and the image sensor. The measuring device may comprise an EUV camera according to the invention.

The illumination system may be configured such that a portion of the photomask is illuminated. The illumination system may be configured such that the intensity of the EUV radiation is substantially uniform within the illuminated portion. The illumination system may comprise one or more EUV mirrors, at which the EUV radiation on the path between the EUV radiation source and the photomask is reflected. The EUV radiation source may be a plasma radiation source, in which a plasma that emits EUV radiation is created. For example, the medium from which the plasma is created may be tin. The plasma can be created by virtue of directing laser beams at a droplet of the medium. The projection lens may comprise a plurality of EUV mirrors, at which the EUV radiation between the photomask and the pellicle is reflected. The measuring device may comprise an EUV radiation source.

The disclosure encompasses developments of the method with features that are described in the context of the EUV camera according to the invention or of the measuring device according to the invention. The disclosure encompasses developments of the EUV camera and of the measuring device with features that are described in the context of the method according to the invention.

### BRIEF DESCRIPTION OF DRAWINGS

The invention is described by way of example hereinafter using advantageous embodiments, with reference to the appended drawings. In the figures:

FIG. 1: shows a schematic illustration of a measuring device according to the invention;

FIG. 2: shows a schematic sectional illustration of an EUV camera according to the invention;

FIG. 3: shows an aspect of the EUV camera from FIG. 2;

FIG. 4: shows a schematic illustration of a photomask;

FIG. 5: shows the view according to FIG. 2 in an alternative embodiment of an EUV camera;

FIG. 6: shows an aspect of the EUV camera from FIG. 5;

FIG. 7: shows a schematic illustration of a measuring device according to the invention;

FIG. 8: shows the view according to FIG. 2 in a further embodiment of an EUV camera;

FIG. 9: shows an aspect of the EUV camera from FIG. 8.

### DETAILED DESCRIPTION

Microlithographic photomasks 17 can be examined using a measuring device according to the invention.

In general, microlithographic photomasks 17 are provided for use in a microlithographic projection exposure apparatus (not depicted here). In the microlithographic projection exposure apparatus, the photomask 17 is illuminated with extreme ultraviolet radiation (EUV radiation) at a wavelength of for example 13 nm in order to image a structure formed on the photomask 17 onto the surface of a lithographic object in the form of a wafer. The wafer is coated with a photoresist that reacts to the EUV radiation. The measuring device is used to examine whether the measuring device meets the requirements and is free from contamination.

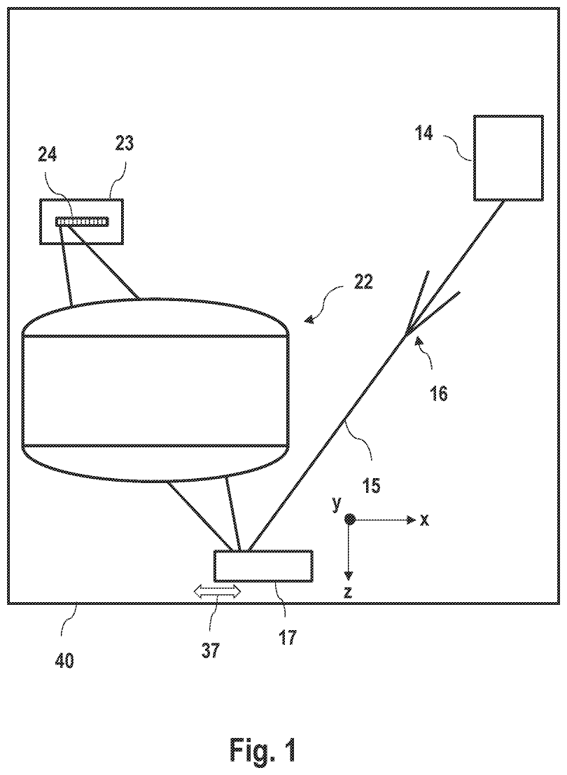

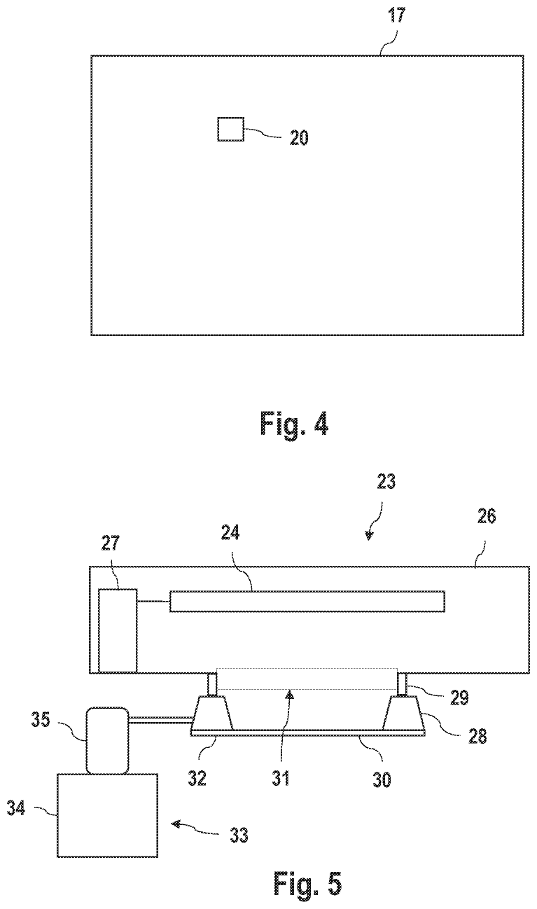

In some implementations, according to FIG. 1, the photomask 17 is arranged in the measuring device such that an EUV beam path 15 emanating from an EUV radiation source 14 is guided via an illumination system 16 to the photomask 17. The illumination system 16 is used to shape the EUV radiation to form a beam used to illuminate, with uniform brightness, an examination field 20 on the surface of the photomask 17. The examination field 20 which is small in comparison with the area of the photomask 17 is depicted in FIG. 4 in an illustration that is not true to scale. For example, the illuminated region of the examination field 20 may have dimensions of 0.5 mm×0.8 mm. The edge lengths of the photomask 17 can be between 100 mm and 200 mm, for example. A field stop used to delimit the illuminated region to the examination field 20 on the surface of the photomask 17 is arranged between the first illumination mirror and the second illumination mirror. Using an XY-positioning mechanism 37, it is possible to move the photomask in the XY-plane in order to bring different examination fields 20 into the region of the EUV beam path 15.

The EUV beam path 15 reflected at the photomask 17 continues through a projection lens 22 to an EUV camera 23, which is equipped with an image sensor 24. The projection lens 22 is used to image the examination field 20 of the photomask 17 on the image sensor 24 of the EUV camera 23. An aperture stop whose aperture corresponds to the first mirror is arranged between the photomask 17 and the first mirror. The EUV radiation source 14, the illumination system 16, the photomask 17, the projection lens 22 and the EUV camera 23 are arranged in a vacuum housing 40, in which a negative pressure prevails during the operation of the measuring device.

For example, the EUV radiation source 14 is a plasma radiation source, in which the EUV radiation is emitted from a plasma at a wavelength of 13 nm. Tin is a medium that can be used to generate a plasma suitable for emitting such EUV radiation. A laser beam can be made to impinge on a droplet of the medium for the purpose of generating the plasma.

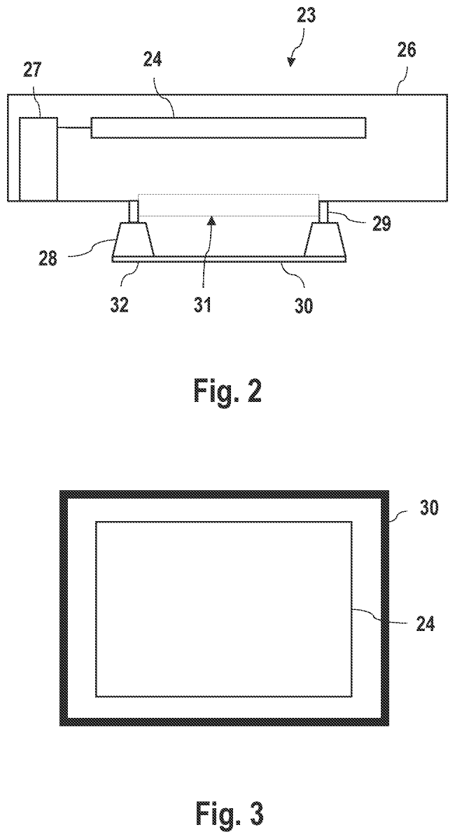

In some implementations, according to FIG. 2, the EUV camera 23 comprises a housing 26, in the interior of which the image sensor 24 and an electronics unit 27 are arranged. The electronics unit 27 is used to control the image sensor 24 and process the EUV image data obtained by the image sensor 24. A connection flange 29 which extends around an entrance opening 31 of the EUV camera 23 is formed on the housing 26. A frame 28 over which a pellicle 30 has been stretched is connected to the connection flange 29. The connection between the frame 28 and the connection flange 29 is a detachable connection such that the pellicle unit 32 comprising the frame 28 and the pellicle 30 can be detached from the housing 26 and replaced by a new pellicle unit. For example, the pellicle unit 32 can be replaced during a servicing procedure, to which the measuring device is subjected at suitable intervals.

Together with the pellicle unit 32, the housing 26 completely encloses the interior of the EUV camera 23. EUV radiation coming from the projection lens 22 enters the interior of the EUV camera 23 through the pellicle 30 and is incident on the image sensor 24. The schematic illustration of FIG. 3 depicts a view of the image sensor 24 through the pellicle 30. The image sensor 24 comprises a sensor area which is occupied by pixels all over and the totality of which can be seen through the pellicle 30 and the totality of which is available for recording an image of the examination field 20 of the photomask 17.

The projection lens 22 has a magnification factor of more than 100. In order to be able to record the entirety of the generated picture of the examination field 20 of the photomask 17, the area of the image sensor 24 is greater than the area of the examination field 20 in accordance with the magnification factor. For example, the image sensor 24 may have dimensions of the order of 100 mm to 200 mm.

Together with the pellicle unit 32, the housing 26 is designed such that a substance exchange between the interior of the EUV camera 23 and the surroundings is largely suppressed, but pressure equalization remains possible. The operation of the measuring device occurs within a vacuum housing 40. During operation of the measuring device, the vacuum pressure in the interior of the EUV camera 23 is the same as in other regions of the vacuum housing 40.

The pellicle 30 is a very thin membrane made of a silicon material which allows good passage of EUV radiation but obstructs the passage of particles. The pellicle 30 ensures that particles contained in the atmosphere of the measuring device cannot penetrate into the interior of the EUV camera 23. Such particles would be bothersome in particular if they landed on the image sensor 24. Particles on the image sensor 24 falsify the recorded pictures of the examination field 20 of the photomask 17.

Conversely, the pellicle 30 also prevents contaminations from being able to leave the interior of the EUV camera 23 and being able to land on other components of the measuring device. In particular, the photomask 17 itself experiencing contamination should be avoided because this may have as a consequence that semiconductor components produced with the photomask 17 at a later stage may be unusable.

Such contamination may result inter alia from outgassing, which may arise in the EUV camera 23 when a vacuum is present in the interior of the EUV camera 23. The EUV camera 23 contains adhesives used for example to connect the electronics unit 27 and the image sensor 24 to the housing 26. The pellicle 30 consisting of a silicon material has the effect that such outgassing can largely be kept in the interior of the EUV camera 23 and at best only a small component thereof may emerge to the outside. The functionality of the EUV camera 23 is not impaired by the outgassing. The outgassing would be damaging if the gas could come into contact with other components of the measuring device outside of the EUV camera 23.

FIG. 5 shows an alternative embodiment of an EUV camera 23, in which the pellicle unit 32 is connected to a mechanism 33 enabling a semi-automatic replacement of the pellicle unit 32. The mechanism 33 comprises a motor 34 which can put a rotary part 35 into rotation. The pellicle unit 32 attached to the rotary part 35 via an arm is pivoted to the side relative to the housing 26 of the EUV camera 23 when the rotary part 35 is rotated. In this way, the pellicle unit 32 can be brought into a position which is easily accessible and in which a used-up pellicle unit 32 can be replaced by a new pellicle unit. The vacuum housing of the measuring device may comprise a flap enabling access to the used-up pellicle unit 32. The vacuum in the vacuum housing is reversed before the flap is opened.

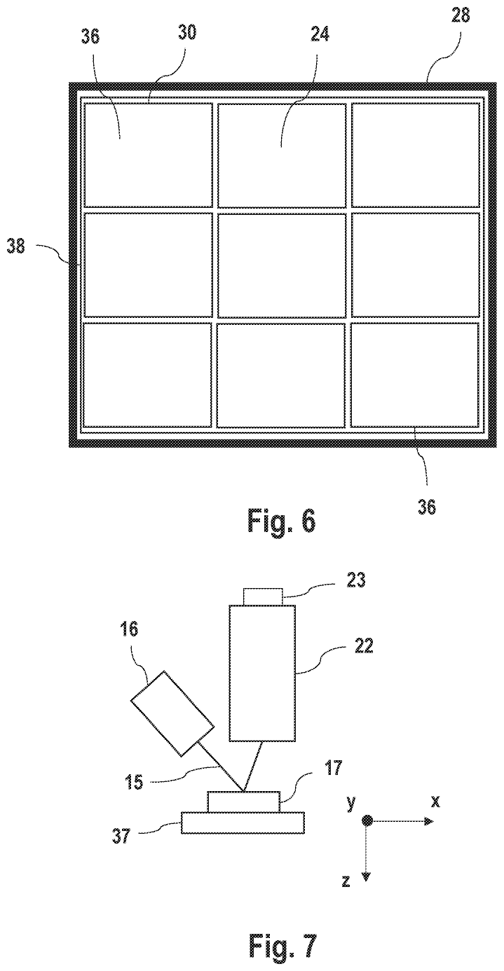

According to FIG. 6, the image sensor 24 comprises a plurality of sensor components 36, a total of nine in the present example. Each sensor component 36 has a sensor area occupied by pixels all over. Narrow pixel-free regions are present at the transition between two adjacent sensor components 36. The pixel-free regions form a grid-shaped pattern on the image sensor 24.

If the sensor area of the image sensor 24 is formed from a plurality of sensor components 36, then this is advantageous in that a large-area image sensor 24 can be assembled from conventional CCD chips that are sensitive to EUV radiation. The fact that between the sensor components 36 there are pixel-free regions in which no EUV image information can be obtained is accepted in this embodiment.

In the exemplary embodiment shown in FIG. 7, the photomask 17 is arranged on an XY-positioning mechanism 37, by means of which the photomask 17 can be displaced within the XY-plane. What can be achieved by displacing the photomask 17 in the XY-plane is that it is not always the same regions of the examination field 20 on the photomask 17 which are incident on the pixel-free regions of the image sensor 24. By recording a plurality of EUV image recordings with slightly different positions of the photomask 17 in the XY-plane, it is possible to obtain EUV image information for each point in the examination field 20. By way of a suitable combination of the EUV image recordings by calculation, it is possible to obtain a picture in which the examination field 20 is depicted without gaps.

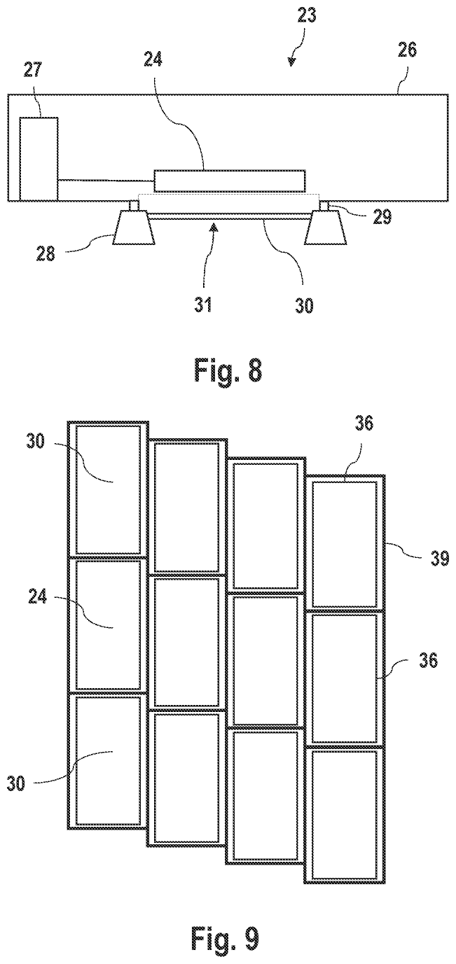

FIGS. 8 and 9 show an exemplary embodiment in which the EUV camera 23 comprises a plurality of pellicles 30, each of which is smaller than the image sensor 24 but together they span the sensor area 38 of the image sensor 24. Each sensor component 36 is assigned a pellicle 30 which is held in a frame part extending around the sensor component 36. Overall, this creates a frame 39 which extends in grid-shaped fashion over the area of the image sensor 24 and whose frame struts are each arranged in the pixel-free regions between the sensor components 36.

According to FIG. 8, the pellicle component made of the plurality of pellicles 30 is arranged at a shorter distance from the image sensor 24 such that, firstly, the EUV picture recorded by the image sensor 24 is not impaired by contamination deposited on the pellicles 30 and that, secondly, the EUV radiation through the struts of the frame 28 is shielded not by the sensor components 36 but primarily by the pixel-free regions between the sensor components 36.

The pellicle component arranged in front of the image sensor 24 prevents particles and outgassing from leaving the interior of the EUV camera 23 and impairing other components of the measuring device. Conversely, particles present in the measuring device are prevented from penetrating into the interior of the EUV camera 23 and landing on the image sensor 24. Particles on the image sensor 24 would impede the EUV image recordings.

If a situation arises in which a fault is visible in an EUV image recording, then it is not readily possible to determine whether this is a contamination on the image sensor 24, a contamination or a fault on the photomask 17 or a fault at any other point in the projection lens 22. To be able to make a distinction between different sources of error, provision can be made for the photomask 17 to be subjected to a slight movement in the XY-plane. A fault moving over the image sensor 24 together with the photomask 17 can be assigned to the photomask 17. A fault maintaining its position on the image sensor 24 unchanged despite the movement of the photomask 17 can be found on the image sensor 24.

It is also possible to replace the photomask 17 with a reference mask whose surface may for example be free from structures. An EUV picture created with such a reference mask should have uniform brightness values over the area of the image sensor 24. The state of the projection lens 22 can be deduced from deviations from the expected brightness distribution.

What is claimed is:

1. A method for inspecting photomasks, wherein a photomask is illuminated by EUV radiation emitted by an EUV radiation source and wherein EUV radiation reflected at the photomask is guided via a projection lens to an image sensor of an EUV camera such that the photomask is imaged on the image sensor, and wherein the EUV radiation passes through a pellicle arranged between the projection lens and the image sensor.

2. The method of claim 1, wherein the EUV radiation passes through the pellicle exactly once between the EUV radiation source and the image sensor.

3. The method of claim 1, wherein the pellicle is a constituent part of the EUV camera.

4. The method of claim 1, wherein a first EUV image recording is recorded by the EUV camera, the photomask being displaced relative to the incident EUV radiation and a second EUV image recording being recorded subsequently.

5. An EUV camera having a camera housing and having an image sensor, the image sensor being held in the camera housing, the image sensor being sensitive to EUV radiation, the camera housing spanning an entrance opening designed for the entry of EUV radiation, and the EUV camera comprising a pellicle such that EUV radiation entering the EUV camera through the entrance opening passes through the pellicle.

6. The EUV camera of claim 5, wherein the pellicle consists of a silicon material.

7. The EUV camera of claim 5, wherein the pellicle is sealingly flush with a housing edge surrounding the entrance opening.

8. The EUV camera of claim 5, wherein the pellicle is mounted on a frame, wherein the pellicle is connected to the camera housing via the frame and wherein the frame is detachably connected to the camera housing.

9. The EUV camera of claim 5, wherein the image sensor is configured as a sensor array, in which the sensor area of the image sensor is spanned by a plurality of sensor components.

10. The EUV camera of claim 5, wherein the EUV camera comprises a pellicle which is smaller than the sensor area of the image sensor.

11. The EUV camera of claim 5, wherein the EUV camera comprises a plurality of pellicles.

12. The EUV camera of claim 11, wherein the plurality of pellicles are arranged in a plane.

13. The EUV camera of claim 11, wherein the plurality of pellicles are held on a frame and wherein parts of the frame are arranged in front of pixel-free regions of the sensor area of the image sensor.

14. A measuring device for inspecting photomasks, comprising an illumination system, a projection lens and an EUV camera, EUV radiation emitted by the EUV radiation source being guided via the illumination system to a photomask, EUV radiation reflected at the photomask being guided via the projection lens to an image sensor of the EUV camera such that the photomask is imaged on the image sensor, and the measuring device comprising a pellicle arranged between the projection lens and the image sensor.

15. The EUV camera of claim 5, wherein the pellicle comprises a silicon-containing material.

16. The EUV camera of claim 5, wherein the pellicle comprises carbon nanotubes.

17. The EUV camera of claim 9, wherein each sensor component comprises a plurality of pixels.

18. The measuring device of claim 14, wherein the pellicle is a constituent part of the EUV camera.

19. The measuring device of claim 18, wherein the EUV camera comprises a plurality of pellicles.

20. The measuring device of claim 19, wherein the plurality of pellicles are arranged in a plane.
